(19) United States
(12) Patent Application Publication
(10) Pub. No.: US 2011/0290293 A1
(43) Pub. Date: Dec. 1, 2011

(54) Thermoelectric module and method for manufacturing the same

(75) Inventors: Yong Suk Kim, Yongin-si (KR); Sung Ho Lee, Seongnam-si (KR); Tae Kon Koo, Seoul (KR); Yong Soo Oh, Seongnam-si (KR)

(73) Assignee: SAMSUNG ELECTRO-MECHANICS CO., Suwon (KR)

(21) Appl. No.: 12/923,079

(22) Filed: Aug. 31, 2010

(30) Foreign Application Priority Data
May 26, 2010 (KR) 10-2010-0049127

(51) Int. Cl. H01L 35/02; H01L 35/34; H01L 21/02

(52) U.S. Cl. 136/200; 438/54; 257/E21.002; 136/201

(57) ABSTRACT

Disclosed herein is a thermoelectric module. The thermoelectric module includes: first and second substrates that are disposed to be separated from each other, facing each other and includes first and second grooves each formed on inner sides thereof; first and second electrodes that are received in the first and second grooves, respectively; and a thermoelectric device that is interposed between the first and second electrodes and is electrically bonded to the first and second electrodes. As a result, the present invention provide a thermoelectric module and a method for manufacturing the same capable of improving the figure of merit and reliability of the thermoelectric module.

### CROSS REFERENCE TO RELATED APPLICATION

This application claims the benefit of Korean Patent Application No. 10-2010-0049127, filed on May 26, 2010, entitled, “Thermoelectric Module And Method For Manufacturing The Same”, which is hereby incorporated by reference in its entirety into this application.

### BACKGROUND OF THE INVENTION

1. Technical Field

The present invention relates to a thermoelectric module, and more particularly, to a thermoelectric module embedding electrodes into a substrate and a method for manufacturing the same.

2. Description of the Related Art

A sudden increase in use of fossil energy causes global warming and exhaustion of energy, such that more searches on a thermoelectric module capable of efficiently using energy have been recently conducted.

The thermoelectric module may be used as a power generator using a Seebeck effect that electromotive force is generated when both ends of the thermoelectric device have difference in temperature or a cooler using a Peltier effect that one end of the thermoelectric device generates heat and the other end thereof absorbs heat when direct current is applied to the thermoelectric device.

The thermoelectric module may include first and second electrodes that are formed on inner sides of two substrates, respectively, and a thermoelectric device interposed between the first and second electrodes. The first and second electrodes may be formed on two substrates, respectively, by a printing process or a plating process. In this case, the bonding between the electrodes and the substrate may be incomplete due to the absence in a bonding surface area between the substrates and the electrodes and precision defect of patterns. In addition, the flatness of the substrates may be degraded during a process of forming the electrodes on the substrates, such that the bonding defect and the contact resistance between the electrodes and the thermoelectric device can be increased.

As described above, the bonding defect between components configuring the thermoelectric module, that is, the bonding defect between the substrates and the electrodes or the electrodes and the thermoelectric device degrades the figure of merit of the thermoelectric module and the thermoelectric module is rapidly deteriorated due to thermal impact, moisture etc permeation, etc., thereby leading to the degradation in the reliability of the thermoelectric module.

### SUMMARY OF THE INVENTION

An object of the present invention is to provide a thermoelectric module capable of securing bonding safety between electrodes and substrates and between the electrodes and thermoelectric devices by embedding the electrodes into the substrates and a method for manufacturing the same.

According to an exemplary embodiment of the present invention, there is provided a thermoelectric module, including: first and second substrates that are separated from each other, facing each other and includes first and second grooves each formed on inner sides thereof; first and second electrodes that are received in the first and second grooves, respectively; and a thermoelectric device that is interposed between the first and second electrodes and is electrically bonded to the first and second electrodes.

Each form of the first and second electrodes have one of a T-shaped type or I-shaped type.

The first and second substrates may be made of a ceramic material.

The first and second electrodes may comprise at least any one or two selected from the group consisting of Ag, Au, Pt, Sn, and Cu.

According to another exemplary embodiment of the present invention, there is provided a method for manufacturing a thermoelectric module, including: forming first and second grooves on first and second substrates, respectively; forming first and second electrodes on the first and second grooves, respectively; and bonding the first and second substrates to interpose a thermoelectric device between the first and second electrodes.

The forming the first and second electrodes may include: filling a conductive material in the first and second grooves, respectively; and sintering the conductive material.

After the forming the first and second electrodes, the first and second electrodes and the thermoelectric device may be bonded to each other by a reflow process at the bonding the first and second substrate after a solder layer is formed between the first electrode and the thermoelectric device and between the thermoelectric device and the second electrode, respectively.

At the bonding the first and second substrates, the first and second electrodes and the thermoelectric device may be bonded to each other by sintering the conductive material filled in the first and second grooves, respectively.

Each form of the first and second electrodes may have one of T-shaped type or I-shaped type by the first and second grooves.

The first and second electrodes may comprise at least any one or two selected from the group consisting of Ag, Au, Pt, Sn, and Cu.

The first and second substrates may be made of a ceramic material.

The method for manufacturing a thermoelectric module may further include after the forming the first and second grooves on the first and second substrates, respectively, performing a lapping surface treatment on the surfaces of the first and second substrates.

The method for manufacturing a thermoelectric module may further include after the performing the lapping surface treatment, performing a cleaning process and a drying process on the first and second substrates.

The method for manufacturing a thermoelectric module may further include performing the lapping surface treatment on the first and second substrates each formed with the first and second electrodes.

### BRIEF DESCRIPTION OF THE DRAWINGS

FIG. 1 is a cross-sectional view of a thermoelectric module according to a first exemplary embodiment of the present invention;

FIG. 2 is a cross-sectional view of a thermoelectric module according to a second exemplary embodiment of the present invention;

FIGS. 3 to 5 are cross-sectional views explaining a method for manufacturing a thermoelectric module according to a third exemplary embodiment of the present invention;

FIG. 6 is a graph comparing the changes in electrical resistance values according to a temperature of the thermoelectric module according to comparative examples and examples 1 and 2;

FIG. 7 is a graph comparing the changes in thermal conductivity by a temperature of the thermoelectric module according to the comparative examples and examples 1 and 2; and

FIG. 8 is a graph comparing the variations in resistance according to a heat cycle of the thermoelectric module depending on the comparative examples and examples 1 and 2.

### DESCRIPTION OF THE PREFERRED EMBODIMENTS

Hereinafter, exemplary embodiments of the present invention will be described in detail with reference to the drawings of a thermoelectric module. The exemplary embodiments of the present invention to be described below are provided by way of example so that the idea of the present invention can be sufficiently transferred to those skilled in the art to which the present invention pertains.

Therefore, the present invention may be modified in many different forms and it should not be limited to the exemplary embodiments set forth herein. In the drawings, the size and the thickness of the device may be exaggerated for convenience. Like reference numerals designate like components throughout the specification.

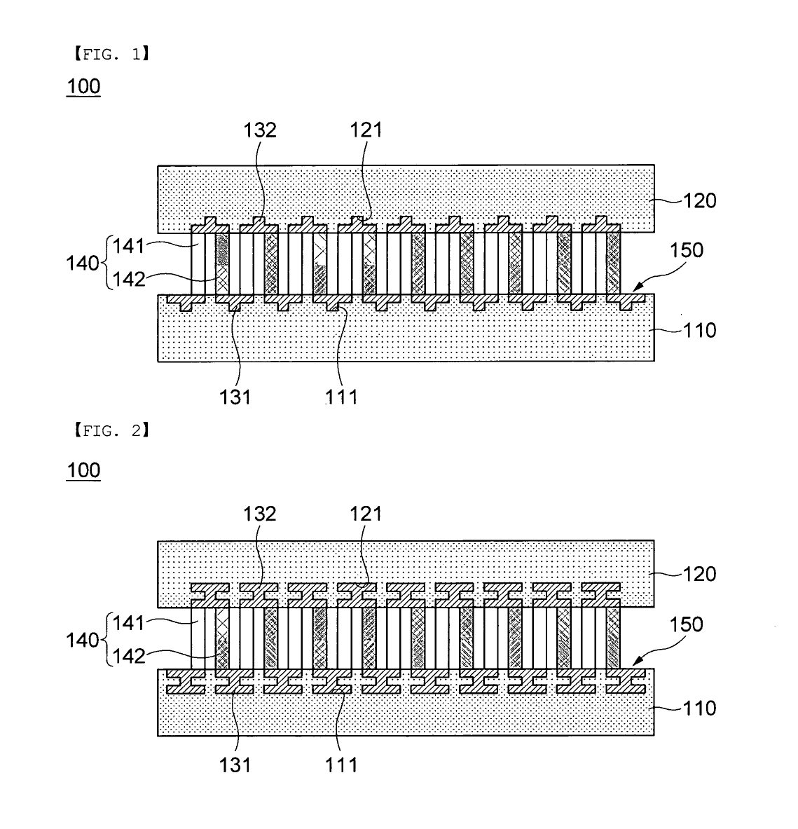

FIG. 1 is a cross-sectional view of a thermoelectric module according to a first exemplary embodiment of the present invention.

Referring to FIG. 1, the thermoelectric module according to the first exemplary embodiment of the present invention may include first and second substrates 110 and 120, first and second electrodes 131 and 132 that are disposed on the inner sides of the first and second substrates 110 and 120, respectively, and a thermoelectric module 140 that is interposed between the first and second electrodes 131 and 132 to be bonded to the first and second electrodes 131 and 132.

The first and second substrates 110 and 120 are spaced apart from each other at a predetermined distance and are disposed to be opposite to each other. The first and second substrates 110 and 120 are made of an insulating material, that is, a ceramic material having excellent thermal conductivity.

In detail, a first groove 111 may be provided in an inner side of the first substrate 110. The first groove 111 may be a space for receiving the first electrode 131 to be described below. In this case, the shape of the first electrode 131 may be determined by the shape of the first groove 111. Herein, a form of the first groove 111 may have a T-shaped type.

The first electrode 131 is filled and received in the first groove 111, such that it may have the T-shaped type. In other words, the first electrode 131 has a structure that can increase a surface area and at the same time, is buried in the first substrate 110, such that the contact area between the first electrode 131 and the first substrate 110 can be increased. Therefore, the contact stability between the first electrode 131 and the first substrate 110 can be increased. In addition, the first electrode 131 is buried in the first substrate 110, such that the thickness of the thermoelectric module can be reduced by the thickness of the first electrode 131. Further, the first electrode 131 is buried in the first substrate 110 to easily prevent the deviation in thickness from occurring at the time of forming the first electrode 131, such that the flatness of the first substrate 110 including the first electrodes 131, respectively, can be secured.

Meanwhile, the second electrode 132 may also be received in the second groove 121 included in the second substrate 120, similar to the first electrode 131 of the first substrate 110. In this case, the structure of the first substrate 110 is the same as the structure of the second substrate 120 and therefore, the description of the second substrate 120 and the second electrode 132 will be omitted.

The first and second electrodes 131 and 132 may comprise at least any one or two selected from a group consisting of Ag, Au, Pt, Sn, and Cu. In this case, the first and second electrodes 131 and 132 may be formed in a single layer structure of single component and a multi-layer structure including at least two layers. Alternatively, the first and second electrodes 131 and 132 may be formed in a single layer structure of a mixture of at least two components.

The thermoelectric device 140 is interposed between the first and second electrodes 131 and 132 and is bonded to the first and second electrodes 131 and 132. In this case, each of the first and second electrodes 131 and 132 is buried in the first and second substrates 110 and 120 and the flatness of the first and second substrates 110 and 120 is maintained, such that the bonding stability between the thermoelectric device 140 and the first and second electrodes 131 and 132 can be secured.

In addition, the electric resistance and the thermal conductivity can be lowered due to the bonding stability between the thermoelectric device 140 and the first and second electrodes 131 and 132, such that the figure of merit of the thermoelectric module 100 can be increased. The reason is that the figure of merit of the thermoelectric module 100 is in inverse proportion to the thermal conductivity and in proportion to the electric conductivity.

The thermoelectric device 140 may include a P-type semiconductor 141 and an N-type semiconductor 142. Herein, the P-type semiconductor 141 and the N-type semiconductor 142 may alternately be arranged on the same plane. In this case, a pair of the P-type semiconductor 141 and the N-type semiconductor 142 may be electrically connected to each other by the first electrode 131 disposed on the lower surface thereof and another pair of adjacent P-type semiconductor 141 and N-type semiconductor 142 may be electrically connected to each other by the second electrode 132 disposed on the upper surface thereof.

The thermoelectric device 140 and the first and second electrodes 131 and 132 may be bonded to each other by a solder layer (not shown). Herein, the solder layer may include Sn such as PbSn or CuAgSn, etc. However, in the exemplary embodiment of the present invention, a material of the solder layer is not limited. Alternatively, the thermoelectric device 140 may be bonded to each other by adhesion of the first and second electrode 131 and 132.

In addition to this, although not shown, one end 150 of the first electrode 131 is connected to the external power, supply unit, such that it May supply power to the external power supply unit or may be supplied with power therefrom. In other words, when the thermoelectric module 100 serves as a power generator, power may be supplied to the external power supply unit and when it serves as a cooler, power may be supplied from the external power supply unit.

Therefore, in the exemplary embodiment of the present invention, the first and second electrodes 131 and 132 are buried in each of the first and second substrates 110 and 120, such that the bonding stability between the first and second substrates 110a and 120 and the first and second electrodes 131 and 132 or between the first and second electrodes 131 and 132 and the thermoelectric device 140 can be secured, thereby making it possible to improve the figure of merit and reliability of the thermoelectric module 100.

In addition to this, the flatness of the thermoelectric module 100 may be maintained due to the burying of the first and second electrodes 131 and 132, such that when the heat sink is further attached to the thermoelectric module 100, the bonding stability between the thermoelectric module 100 and the heat sink can be secured, thereby making it possible to increase the heat-radiating efficiency.

Although the exemplary embodiment of the present invention describes that each of the first and second electrodes have the T-shaped type, the shape of the electrode included in the thermoelectric module can be variously changed.

The thermoelectric module having an electrode having other shapes will now be described with reference to FIG. 2.

FIG. 2 is a cross-sectional view of the thermoelectric module according to the second exemplary embodiment.

Except for the shape of the first and second electrodes, the second exemplary embodiment has the same technical configuration as the thermoelectric module according to the foregoing first exemplary embodiment and therefore, the overlapping description with the first exemplary embodiment will be omitted.

Referring to FIG. 2, the thermoelectric module according to the second exemplary embodiment of the present invention may includes the first and second substrates 110 and 120 included in each of the inner sides of the first and second grooves 111 and 121, the first and second electrodes 131 and 132 received in each of the first and second grooves 111 and 121, and the thermoelectric device 140 that is interposed between the first and second electrodes 131 and 132 and is electrically bonded to the first and second electrodes 131 and 132.

Herein, each form of the first and second grooves 111 and 121 may have an I-shaped type. In this case, the first and second electrodes 131 and 132 filled inside the first and second grooves 111 and 121 may also have the I-shaped type.

Therefore, the first and second electrodes 131 and 132 may further increase the surface area that may contact the first and second substrates 110 and 120, such that the bonding stability between the first and second substrates 110 and 120 and the first and second electrodes 131 and 132 can be further increased, thereby making it possible to further increase the figure of merit and reliability of the thermoelectric module.

Although the exemplary embodiments of the present invention describes only the case where each of the first and second electrodes 131 and 132 are formed in the T-shaped type or the I-shaped type, the first and second electrodes 131 and 132 may be formed in various shapes such as rectangular, squared, and circular section shapes.

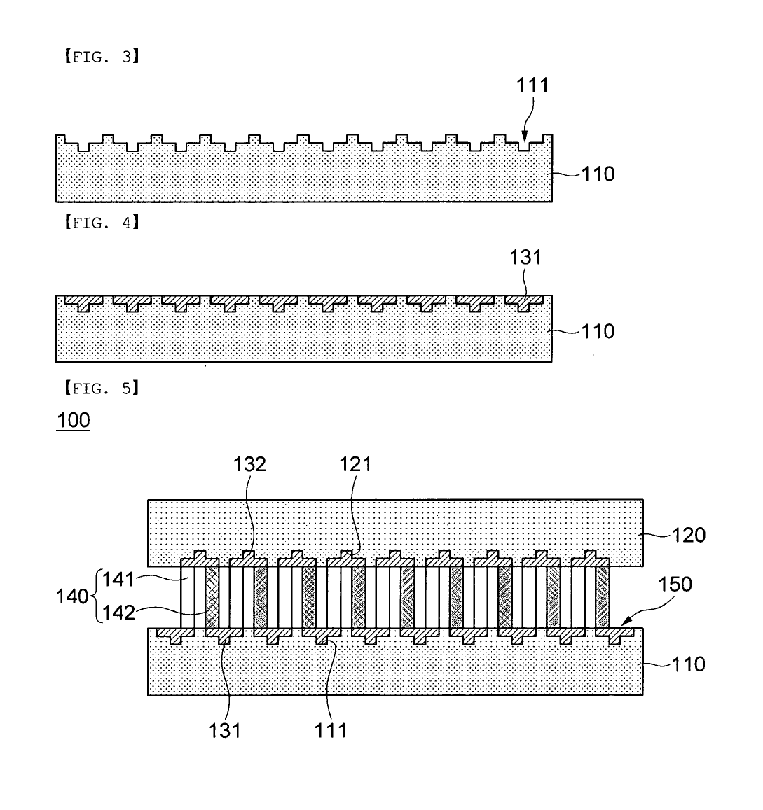

Hereinafter, a method for manufacturing a thermoelectric module according to a third exemplary embodiment of the present invention will be described in detail with reference to FIGS. 3 to 5.

FIGS. 3 to 5 are cross-sectional views showing a method for manufacturing a thermoelectric module according to a third exemplary embodiment according to the present invention.

Referring to FIG. 3, the first substrate 110 is first provided in order to manufacture the thermoelectric module. Herein, the first substrate 110 may be made of a ceramic material as an insulating material.

Thereafter, the first groove 111 is formed in the first substrate 110. Herein, in order to form the first groove 111, a mask pattern formed of a laser marking or a resist pattern is formed on the first substrate 110. Thereafter, the first groove 111 is selectively formed on the first substrate 110 by the laser processing using the mask pattern.

The shape of the first groove 111 may serve to define the shape of the first electrode 131 to be formed in a subsequent process. Herein, the form of the first groove 111 may have a T-shaped type. However, the exemplary embodiment of the present invention is not limited thereto and therefore, the form of the first groove 111 may also have an I-shaped type as an example of another shape. In this case, the first substrate having the I-shaped type may be formed by combining a first ceramic sheet including the groove having the T-shaped type on the surface thereof and a second ceramic sheet including a groove having a ‘−’-shaped type.

In addition to this, after the first groove 111 is formed, the surface of the first substrate 110 including the first groove 111 may be further subjected to a lapping surface treatment. As a result, the impurity generated during a process of machining the first groove 111 can be removed while improving the flatness of the first substrate 110. Herein, the lapping surface treatment may use at least any one abrasive of silicon carbide (SiC), alumina, and boron. Alternatively, the lapping surface treatment may be performed by applying a material having magnetism to the first substrate 110 and then, applying electromagnet, magnetic field, and ultrasonic wave thereto.

Further, the surface treatment is performed and then, a cleaning process and a drying process may further be performed in order to remove organic and inorganic materials and foreign materials remaining on the first substrate 110.

Referring to FIG. 4, the first groove 111 is formed and then, a conductive material is filled in the first groove 111. The conductive material may comprise at least any one or two selected from the group consisting of Ag, Au, Pt, Sn, and Cu.

In this case, the conductive material may be applied in a single layer structure of single component or a multi-layer structure including at least two layers. Alternatively, the conductive material may be applied in the single layer structure of a mixture of at least two components.

The filling of the conductive material may be made by a screen printing method, an inkjet printing method, and a plating method. As other methods for filling the conductive material, a sputtering method, an E-beam method, a CVD method, and a cold spray method, etc. may be used.

Thereafter, the first electrode 131 may be formed by sintering the conductive material. In this case, the first electrode 131 is filled in the first groove 111 and is then sintered, such that the first electrode 131 may be formed to have the same shape as the first groove 111. In other words, the form of the first electrode 131 may have a T-shaped type or the I-shaped type.

Therefore, the contact surface area between the first substrate 110 and the first electrode 131 can be increased, such that the bonding stability between the first substrate 110 and the first electrode 131 can be secured.

Further, the first electrode 131 is formed by being filled in the first groove 111 formed on the first substrate 110 to easily prevent the deviation in thickness of the first electrode 131 from occurring, such that the flatness of the first substrate 110 including the first electrode 131 can be maintained.

In addition to this, after the first electrode 131 is formed, the first substrate 110 including the first electrode 131 is further subjected to the lapping surface treatment, thereby making it possible to further improve the flatness of the first substrate 110 including the first electrode 131.

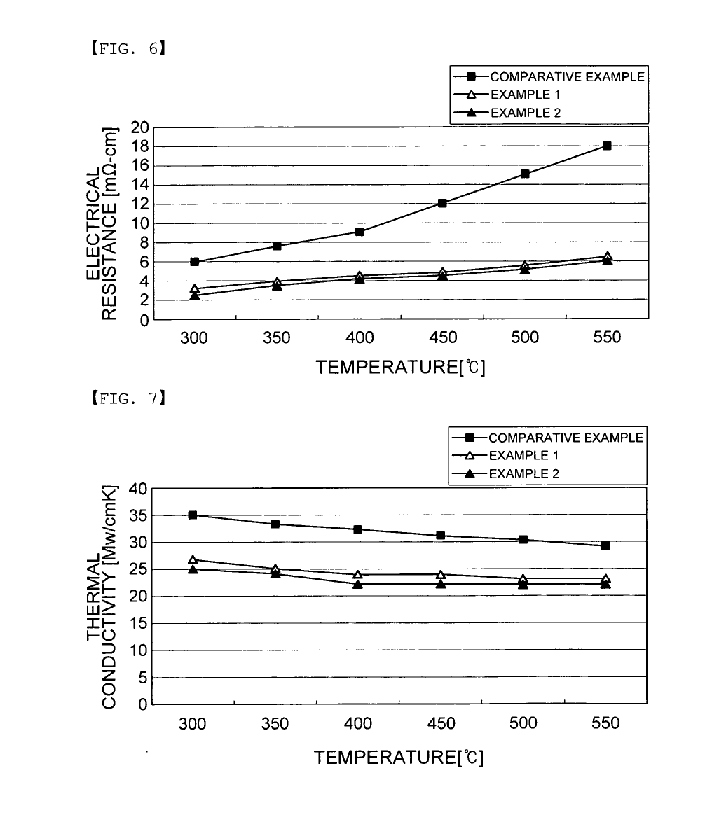

Referring to FIG. 5, the second substrate 120 including the second electrode 132 is provided. The process of forming the second electrode 132 in the second substrate 120 is the same as the foregoing process of forming the first electrode 131 on the first substrate 110. For convenience of explanation, the process of forming the second electrode 132 on the second substrate 120 will be omitted.

Thereafter, the thermoelectric device 140 is interposed and bonded between the first and second electrodes 131 and 132. Herein, the bonding of the thermoelectric device 140 first forms the solder layer (not shown) on the first electrode 131 and the second electrode 132, respectively. The solder layer may be formed by printing conductive paste including Sn such as PbSn or CuAgSn, etc. After the solder layer is formed, the thermoelectric device 140 is disposed on the solder layer. Herein, the thermoelectric device 140 may include the P-type semiconductor 141 and the N-type semiconductor 142. In this case, the P-type semiconductor 141 and the N-type semiconductor 142 may be alternately arranged to each other. Thereafter, the second substrate 120 is disposed on the first substrate 110 so that the thermoelectric device 140 and the solder layer of the second electrode 132 contacts each other and then, the first and second electrodes 131 and 132 and the thermoelectric device 140 are bonded to each other by the reflow process, thereby making it possible to manufacture the thermoelectric module 100.

The exemplary embodiment of the present invention describes the case where the first and second electrodes 131 and 132 and the thermoelectric device 140 are bonded to each other by using the solder layer, but is not limited thereto. For example, the conductive material is filled in the first and second grooves 111 and 121 and then, the thermoelectric device 140 is disposed on the conductive material and is subjected to the sintering process, thereby making it possible to bond the thermoelectric device to the first and second electrode while foaming the first and second electrodes 131 and 132. In other words, the first and second electrodes 131 and 132 and the thermoelectric device 140 may be bonded to each other by the adhesion of the first and second electrodes 131 and 132.

In addition to this, one end 150 of the first electrode 131 is further subjected to the process of connecting with the external power supply unit, such that the thermoelectric module 100 may supply power to the external power supply unit or may be supplied with power therefrom.

In addition, the process of attaching the heat sink to one surface of the thermoelectric module 100, that is, one surface of the first substrate 110 or the second substrate 120 may be further performed. In this case, the thermoelectric module 100 may maintain the flatness, such that the bonding stability between the thermoelectric module 100 and the heat sink can be secured, thereby making it possible to increase the heat-radiating effect.

Hereinafter, the effect of the exemplary embodiments of the present invention can be confirmed with reference to Table 1 and FIGS. 6 to 8.

The thermoelectric module according to the comparative example is manufactured by forming each of the first and second electrodes on the surfaces of the first and second substrates and then, interposing and bonding the thermoelectric device between the first and second electrodes. In this case, the P-type semiconductor device in the thermoelectric device is made of Bi₂Te₃ and the N-type semiconductor device in the thermoelectric device is made of Sb₂Te₃.

Further, the thermoelectric module according to experimental example 1 was manufactured by the same structure and method as the comparative example except for including each of the first and second electrodes having the T-shaped type buried in the first and second substrates.

Further, the thermoelectric module according to experimental example 2 was manufactured by the same structure and method as the comparative example except for including each of the first and second electrodes having the I-shaped type buried in the first and second substrates.

FIG. 6 is a graph comparing the changes in electrical resistance values according to a temperature of the thermoelectric module according to comparative examples and exemplary embodiments 1 and 2.

As shown in FIG. 6, it can be appreciated that the electrical resistance is lower in the case where the electrode is buried in the substrate than in the case where the electrode is formed on the surface of the substrate. That is, it can be confirmed that the electric conductivity is further increased in the case where the electrode is buried in the substrate than in the case where the electrode is formed on the surface of the substrate.

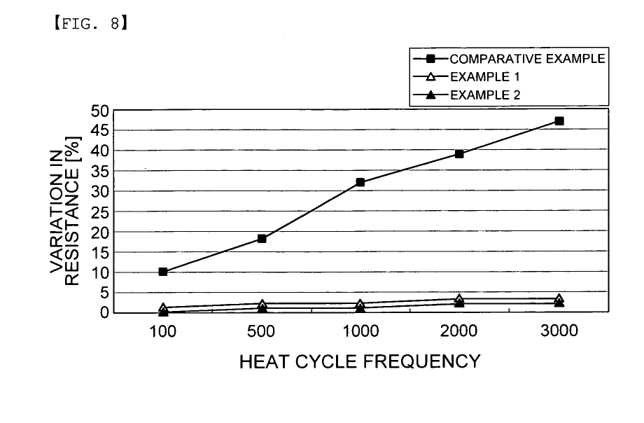

FIG. 7 is a graph comparing the changes in thermal conductivity according to a temperature of the thermoelectric module according to a comparative example and examples 1 and 2.

As shown in FIG. 7, it can be appreciated that the thermal conductivity is lower in the case where the electrode is buried in the substrate than in the case where the electrode is formed on the surface of the substrate.

The following Table 1 is a table comparing the figure of merit of the thermoelectric module according to the comparative example and the examples 1 and 2. Herein, data described in Table 1 are values calculated as an average value after collecting five samples from the thermoelectric modules each manufactured according to the comparative example and the examples 1 and 2 and measuring the merit of figure thereof.

TABLE 1

| | Comparative | | |
|---|---|---|---|
| | Example | Example 1 | Example 2 |
| Figure of merit | 0.8020 | 0.8252 | 0.8447 |

As described in Table 1, it can be appreciated that the electric conductivity is further increased and the figure of merit is further increased as the thermal conductivity is lowered, in the case where the electrode is buried in the substrate than in the case where the electrode is formed on the surface of the substrate.

FIG. 8 is a graph comparing the variations in resistance according to a heat cycle of the thermoelectric module according to the comparative examples and the examples 1 and 2. Herein, the heat cycle was performed in the temperature range of −40° C. to +40° C. for 15 minutes.

As shown in FIG. 8, it can be appreciated that the variations in resistance according to the heat cycle is maintained to be approximately constant, in the case where the electrode is buried in the substrate than in the case where the electrode is formed on the surface of the substrate.

Therefore, it can be confirmed that the reliability of the thermoelectric module is further increased in the case where the electrode is buried in the substrate than in the case where the electrode is formed on the surface of the substrate.

Therefore, as in the exemplary embodiment of the present invention, the electrode is formed to be buried in the substrate to prevent the deviation in thickness of the electrode from occurring due to the groove formed in the substrate, thereby making it possible to improve the flatness of the substrate as well as the thermoelectric module that is a final product. Therefore, the present invention can increase the contact area between the substrate and the electrode and secure the bonding stability between the substrate and the electrode and between the electrode and the thermoelectric device, thereby making it possible to improve the figure of merit and the reliability of the thermoelectric module.

The thermoelectric module of the present invention can secure the bonding safety between the substrates and the electrodes by embedding the electrodes into the substrates.

Further, the thermoelectric module of the present invention can maintain the flatness of the substrates by embedding the electrodes into the substrates, thereby making it possible to secure the bonding safety between the electrodes and the thermoelectric devices.

In addition, the thermoelectric module of the present invention can secure the bonding safety between the substrates and the electrodes and the electrodes and the thermoelectric devices, thereby making it possible to improve the figure of merit and reliability of the thermoelectric module.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood as falling within the scope of the present invention.

What is claimed is:

1. A thermoelectric module, comprising:
first and second substrates that are separated from each other, facing each other and includes first and second grooves each formed on inner sides thereof;
first and second electrodes that are received in the first and second grooves, respectively; and
a thermoelectric device that is interposed between the first and second electrodes and is electrically bonded to the first and second electrodes.

2. The thermoelectric module according to claim 1, wherein each form of the first and second electrodes have one of a T-shaped type or I-shaped type.

3. The thermoelectric module according to claim 1, wherein the first and second substrates are made of a ceramic material.

4. The thermoelectric module according to claim 1, wherein the first and second electrodes comprises at least any one or two selected from the group consisting of Ag, Au, Pt, Sn, and Cu.

5. A method for manufacturing a thermoelectric module, comprising:
forming first and second grooves on first and second substrates, respectively;
forming first and second electrodes on the first and second grooves, respectively; and
bonding the first and second substrates to interpose a thermoelectric device between the first and second electrodes.

6. The method for manufacturing a thermoelectric module according to claim 5, wherein the forming the first and second electrodes includes:
filling a conductive material in the first and second grooves, respectively; and
sintering the conductive material.

7. The method for manufacturing a thermoelectric module according to claim 6, wherein after the forming the first and second electrodes, the first and second electrodes and the thermoelectric device are bonded to each other by a reflow process at the bonding the first and second substrates after a solder layer is formed between the first electrode and the thermoelectric device and between the thermoelectric device and the second electrode, respectively.

8. The method for manufacturing a thermoelectric module according to claim 5, wherein at the bonding the first and second substrates, the first and second electrodes and the thermoelectric device are bonded to each other by sintering the conductive material filled in the first and second grooves, respectively.

9. The method for manufacturing a thermoelectric module according to claim 5, wherein each form of the first and second electrodes have one of T-shaped type or I-shaped type by the first and second grooves.

10. The method for manufacturing a thermoelectric module according to claim 5, wherein the first and second electrodes include comprises any one or two selected from the group consisting of Ag, Au, Pt, Sn, and Cu.

11. The method for manufacturing a thermoelectric module according to claim 5, wherein the first and second substrates are made of a ceramic material.

12. The method for manufacturing a thermoelectric module according to claim 5, further comprising after the forming the first and second grooves on the first and second substrates, respectively, performing a lapping surface treatment on the surfaces of the first and second substrates.

13. The method for manufacturing a theLmoelectric module according to claim 11, further comprising after the performing the lapping surface treatment, performing a cleaning process and a drying process on the first and second substrates.

14. The method for manufacturing a thermoelectric module according to claim 5, further comprising performing the lapping surface treatment on the first and second substrates each formed with the first and second electrodes.
